(19) United States
(12) Patent Application Publication
(10) Pub. No.: US 2013/0302952 A1
(43) Pub. Date: Nov. 14, 2013

(54) METHOD FOR MANUFACTURING A SEMICONDUCTOR DEVICE

(71) Applicants: Jun Luo, Beijing (CN); Jian Deng, Beijing (CN); Chao Zhao, Kessel-lo (BE); Junfeng Li, Beijing (CN); Dapeng Chen, Beijing (CN)

(72) Inventors: Jun Luo, Beijing (CN); Jian Deng, Beijing (CN); Chao Zhao, Kessel-lo (BE); Junfeng Li, Beijing (CN); Dapeng Chen, Beijing (CN)

(21) Appl. No.: 13/580,963

(22) PCT Filed: Jun. 7, 2012
(86) PCT No.: PCT/CN12/00780

§ 371 Date: Aug. 24, 2012

(30) Foreign Application Priority Data
May 11, 2012 (CN) 201210147554.5
Jun. 7, 2012 (CN) PCT/CN2012/000780

(51) Int. Cl. H01L 21/336

(52) U.S. Cl. 438/163; 438/305; 257/E21.409; 257/E21.415

(57) ABSTRACT

The present invention discloses a method for manufacturing a semiconductor device, comprising the steps of: forming a gate stack structure on a substrate; forming source and drain regions as well as a gate spacer on both sides of the gate stack structure; depositing a first metal layer on the source and drain regions; performing a first annealing such that the first metal layer reacts with the source and drain regions, to epitaxially grow a first metal silicide; depositing a second metal layer on the first metal silicide; and performing a second annealing such that the second metal layer reacts with the first metal silicide as well as the source and drain regions, to form a second metal silicide. In accordance with the method for manufacturing a semiconductor device of the present invention, by means of epitaxially growing an ultra-thin metal silicide on the source and drain regions, the grain boundaries among silicide particles are minimized or eliminated, the metal diffusion speed and direction are limited, thus the lateral growth of the metal silicide is suppressed and the device performance is further increased.

### CROSS REFERENCE

This application is a National Phase application of, and claims priority to, PCT Application No. PCT/CN2012/000780, filed on Jun. 7, 2012, entitled ‘METHOD FOR MANUFACTURING A SEMICONDUCTOR DEVICE’, which claimed priority to Chinese Application No. CN 201210147554.5, filed on May 11, 2012. Both the PCT Application and Chinese Application are incorporated herein by reference in their entireties.

### FIELD OF THE INVENTION

The present invention relates to a method for manufacturing a semiconductor device, in particular relates to a method for manufacturing a semiconductor device that effectively controls the lateral extension of a metal silicide and decreases the source/drain contact resistance.

### BACKGROUND OF THE INVENTION

The device size is required to be scaled down as the IC integration level constantly increases, but sometimes an electronic appliance operates at a constant voltage, causing the electrical field intensity in a MOS device to be continuously increased. High-electrical field causes a series of problems concerning reliability, resulting in deterioration in the device performance. For example, the parasitic series resistance between the source and drain regions of an MOSFET may cause deterioration in the equivalent operating voltage, and may cause deterioration in the device performance.

A device structure that is capable of effectively decreasing the source-drain resistance is to form a metal silicide, which is generally the corresponding silicide of a Ni-based metal such as Ni, NiPt, NiCo, and NiPtCo, in a substrate using a self-aligning silicide process. The formation method is generally achieved by sputtering a Ni-based metal on the gate stack structure and the substrate on both sides of the gate spacer in a device, then performing a rapid thermal annealing at a lower temperature (e.g., 450-550 □) such that the Ni-based metal reacts with the silicon in the substrate to form a Ni-based metal silicide having a lower thin film resistance, which directly functions as the source and drain regions of the device, to thereby decrease the source-drain contact resistance and parasitic resistance effectively.

However, since the Ni-based metal is located not only at the place where the source and drain regions to be formed in the substrate but also on the gate spacer and the gate stack, and a rapid thermal annealing is performed in the silicide process, the Ni-based metal not only reacts with the exposed substrate, a portion of the Ni-based metal will diffuse to the bottom of the gate spacer, causing the formed Ni-based metal silicide to diffuse laterally to infringe the bottom of the gate spacer, even enter into the channel region. With the development of the device process to sub-50 nm node, the lateral extension of the above Ni-based metal silicide will cause serious problems, e.g., the gate leakage current is increased, the device reliability is decreased, the source and drain regions may possibly be jointed to short-circuit, the control on the channel region by the gate is weakened, and the finally a device failure is caused. Particularly, since the Si layer on the top of SOI is rather thin, low Si content may cause the problem of lateral diffusion of metal silicide more serious.

For such problem of lateral diffusion, a solution is to adopt a method of two steps of annealing. Specifically, a Ni-based metal layer is deposited on the gate stack structure, both sides of the gate spacer, and the substrate on both sides, a first annealing at a lower temperature, e.g., about 300° C. is performed such that the Ni-based metal layer reacts with the Si in the substrate to form Ni-rich phase metal silicide. Since the first annealing temperature is low enough to suppress the diffusion of Ni-based metal, fewer Ni-rich phase metal silicide formed by the reaction extends to the bottom of the gate spacer, not even to rush into the channel region. After stripping off the unreacted Ni-based metal layer, a second annealing at a higher temperature, e.g., 450˜500 □ is performed such that the Ni-rich phase metal silicide is converted to the Ni-based metal silicide that has a lower resistance. However, in the above method, due to residuals of Ni-based metal layer on the gate spacer caused by incomplete stripping, or due to high content of Ni-based metal in the Ni-rich phase metal silicide, there still will be a small amount of Ni-based metal silicide rush into the bottom of the gate spacer during the second annealing, or enter into the channel region even connect the source and drain regions in severe cases, resulting in a decrease in the device performance or a device failure.

In summary, the lateral extension of Ni-based metal silicide is difficult to be completely suppressed in the prior art, which seriously restricts improvement in the device performance.

### SUMMARY OF THE INVENTION

As stated above, the present invention aims to provide a method for manufacturing a semiconductor device that is capable of effectively suppressing the lateral extension of a metal silicide.

Therefore, the present invention provides a method for manufacturing a semiconductor device, comprising the steps of: forming a gate stack structure on a substrate; forming source and drain regions as well as a gate spacer on both sides of the gate stack structure; depositing a first metal layer on the source and drain regions; performing a first annealing such that the first metal layer reacts with the source and drain regions, to epitaxially grow a first metal silicide; depositing a second metal layer on the first metal silicide; and performing a second annealing such that the second metal layer reacts with the first metal silicide as well as the source and drain regions, to form a second metal silicide.

Wherein the gate spacer comprises one of an oxide and a nitride, or a combination thereof.

Wherein the step for forming source and drain regions as well as the gate spacer further comprises: performing a first source/drain ion implantation by taking the gate stack structure as a mask, to form lightly-doped source and drain extension regions in the substrate on both sides of the gate stack structure; forming a gate spacer in the substrate on both sides of the gate stack structure; performing a second source/drain ion implantation by taking the gate spacer as a mask, to form heavily-doped source and drain regions in the substrate on both sides of the gate spacer; and performing annealing to activate the doped ions.

Wherein the substrate comprises one of bulk Si and SOI.

Wherein the first metal layer and/or the second metal layer is a Ni-based metal layer, including one of Ni, Ni—Pt, Ni—Co and Ni—Pt—Co, or combinations thereof. Wherein the total content of non-Ni elements in the first metal layer is less than or equal to 10%.

Wherein the first metal layer has a thickness of about 0.5˜5 nm.

Wherein the second metal layer has a thickness of about 1˜100 nm.

Wherein the first metal silicide has a thickness of about 1˜9 nm.

Wherein the first metal silicide comprises one of NiSi_{2-y}, NiPtSi_{2-y}, NiCoSi_{2-y} and NiPtCoSi_{2-y}, or combinations thereof, where 0≦y<1.

Wherein the second metal silicide comprises one of NiSi, NiPtSi, NiCoSi and NiPtCoSi, or combinations thereof.

In accordance with the method for manufacturing a semiconductor device of the present invention, by means of epitaxially growing an ultra-thin metal silicide on the source and drain regions, the grain boundaries among silicide particles are minimized or eliminated, the metal diffusion speed and direction are limited, thus the lateral growth of the metal silicide is suppressed and the device performance is further increased.

### BRIEF DESCRIPTION OF THE DRAWINGS

The technical solution of the present invention will be described in detail with reference to the drawings below, wherein:

FIGS. 1 to 5 are diagrammatic cross-sections of the steps of the method for manufacturing a semiconductor device in accordance with the present invention; and

FIG. 6 is flow chart for the method for manufacturing a semiconductor device in accordance with the present invention.

### DETAILED DESCRIPTION OF THE EMBODIMENTS

The features and the technical effects of the technical solution of the present application will be described in detail in combination with the illustrative embodiments with reference to the drawings, and disclosed herein a method for manufacturing a semiconductor device that is capable of effectively suppressing the lateral extension of a metal silicide. It should be pointed out that like reference signs indicate like structures, the terms such as “first”, “second”, “on”, “below” used in the present invention may be used to modify various device structures or manufacturing processes. Except for specific explanations, these modifications do not imply the spatial, sequential or hierarchical relationships of the structures of the modified device or the manufacturing processes.

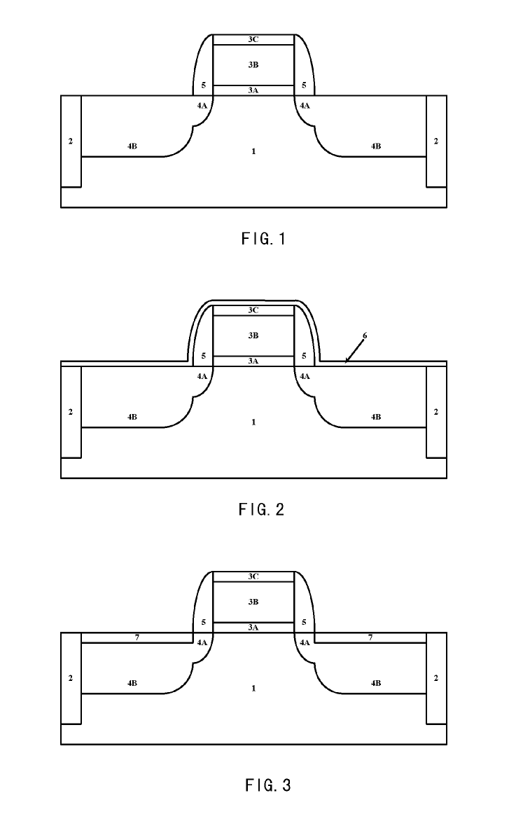

FIGS. 1-5 are diagrammatic cross-sections of the steps of the method for manufacturing a semiconductor device in accordance with the present invention.

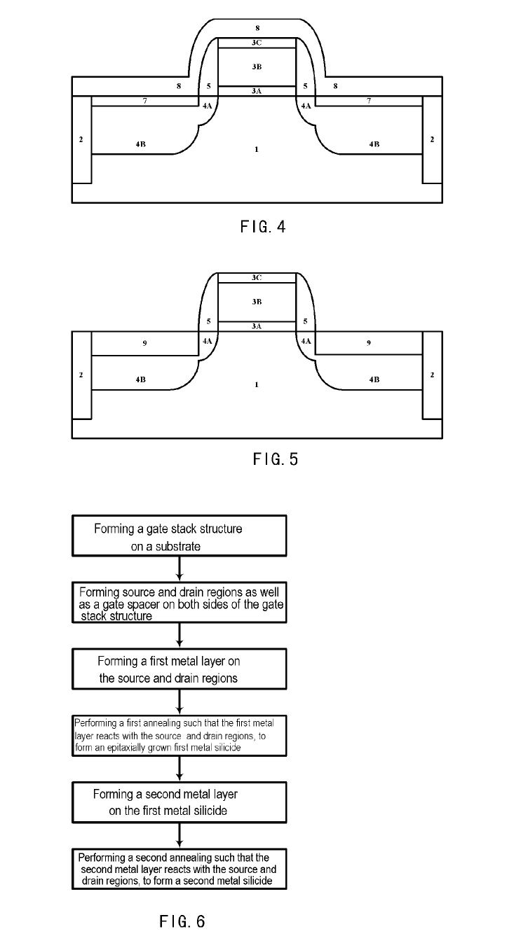

Referring to FIGS. 6 and 1, a basic MOSFET structure is formed, that is, a gate stack structure 3 is formed on a substrate 1, source and drain regions 4 are formed in the substrate 1 on both sides of the gate stack structure 3, and a gate spacer 5 is formed in the substrate 1 on both sides of the gate stack structure.

There is provided a substrate 1, which is made of silicon-contained materials such as bulk silicon (Si), silicon on insulator (SOI), SiGe, SiC, strained silicon, silicon nanotube and so on, and bulk Si or SOI is preferably used. Active region isolations 2 are formed in the substrate 1, for example, shallow trenches are formed by etching, then an insulating material such as silicon oxide is filled to form shallow trench isolations (STI 2).

A gate insulating layer 3A, a gate filling layer 3B, and a gate cap layer 3C are sequentially formed on the substrate 1 in an active region by conventional processes such as LPCVD, PECVD, HDPCVD, ALD, MBE, MOCVD and sputtering, and are etched to form the gate stack structure 3. In a gate-first process, the gate stack structure 3 is retained in the following process, so the gate insulating layer 3A is made of silicon oxide or high-K materials including but not limited to nitride (such as SiN, AlN, and TiN), metal oxide (mainly the oxide of subgroup and lanthanide metal elements such as Al₂O₃, Ta₂O₅, TiO₂, ZnO, ZrO₂, HfO₂, CeO₂, Y₂O₃), and perovskite oxide (such as PbZrₓTi₁₋ₓO₃ (PZT) and BaₓSr₁₋ₓTiO₃(BST)); the gate filling layer 3B comprises one of doped polysilicon, metal, metal alloy and metal nitride, or combinations thereof, wherein the metal comprises, e.g., one of W, Cu, Mo, Ti, Al and Ta, or combinations thereof; and the gate cap layer 3C is made of, e.g., silicon nitride, for protecting the gate stack structure. In a gate-last process, the gate stack structure 3 is a dummy gate stack structure, which shall be removed by etching upon formation of the source and drain regions and shall be refilled, thus the gate insulating layer 3A is made of silicon oxide, the gate filling layer 3B is made of one of polysilicon, microcrystalline silicon and amorphous silicon, or combinations thereof, and the gate cap layer 3C is still made of silicon nitride.

The gate stack structure 3 is taken as a mask to perform a low-dose and low-energy first source/drain ion implantation, to thereby form lightly-doped source and drain extension regions 4A in the substrate 1 on both sides of the gate stack structure 3.

An insulating medium is deposited on the gate stack structure 3, and etching is performed to the structure form a gate spacer 5, the material thereof includes one of an oxide and a nitride, or combination thereof, such as silicon nitride, silicon oxynitride, diamond like amorphous carbon (DLC), high-stress metal oxide (with a stress greater than 1 GPa) and the combinations thereof. The gate spacer 5 may either be a single layer, or a laminated layer of the above materials such as an oxide-nitride-oxide (ONO) structure, or a laminated structure of nitride and DLC.

The gate spacer 5 is taken as a mask to perform a high-dose and high-energy second source/drain ion implantation, to thereby form heavily-doped source and drain extension regions 4B in the substrate 1 on both sides of the gate spacer 5. The type and concentration of the two ion implantations can be reasonably set depending on the requirement of the conductivity type of the device, annealing is performed after the ion implantation, so as to activate the doped ions, and the temperature and time for annealing shall be set depending on the requirement of the doping concentration and depth.

Referring to FIGS. 6 and 2, a first metal layer 6 is formed by deposition on the entire device by conventional processes such as PECVD, MOCVD, and sputtering, thereby covering the STIs 2, source and drain regions 4 and the gate stack structure 3. The first metal layer 6 is made of nickel-based metal e.g., including one of Ni, Ni—Pt, Ni—Co and Ni—Pt—Co, or combinations thereof, preferably the total content of the non-Ni elements (Pt and/or Co) therein is less than or equal to 10% (mole ratio). The first metal layer 6 has an ultra-thin thickness such that the first metal silicide epitaxially grown by annealing later can be thin enough to have substantially no or very few grain boundaries only. The first metal layer 6 may, e.g., have a thickness of about 0.5˜5 nm.

Referring to FIGS. 6 and 3, a first annealing is performed such that the first metal layer 6 reacts with the Si in the source and drain regions 4 (specifically the heavily-doped source and drain regions 4B) to produce a first metal silicide 7. The first annealing may be, e.g., annealing for 30s at 450˜500 □ such that the above ultra-thin first meta layer 6 reacts with the Si in the heavily-doped source and drain regions 4B, to epitaxially grow the first metal silicide 7, including one of NiSi_{2-y}, NiPtSi_{2-y}, NiCoSi_{2-y} and NiPtCoSi_{2-y}, or combinations thereof, where 0≦y<1. The first metal silicide may have a thickness of, e.g., about 1˜9 nm. Then, the residual part of the unreacted first metal layer 6 is stripped off. Since the thickness of the first metal layer 6 is thin enough, Ni can insufficiently diffuse to the channel region to react at the lower annealing temperature, then as shown in FIG. 3, the end face of the first metal silicide 7 adjacent to the channel region is flush with the side face of the gate spacer 5, that is, the first metal silicide 7 will not extend laterally, and will not even enter into the channel region.

Referring to FIGS. 6 and 4, a second metal layer 8 is formed by deposition on the entire device by conventional processes such as PECVD, MOCVD, and sputtering, thereby covering the STIs 2, the first metal silicide 7, and the gate stack structure 3. The second metal layer 8 may be made of a material which is the same or similar to that of the first metal layer 6, e.g., may also include one of Ni, Ni—Pt, Ni—Co and Ni—Pt—Co, or combinations thereof, preferably the total content of non-Ni elements (Pt and/or Co) therein is less than or equal to 10% (mole ratio). However, the second metal layer 8 has a thickness greater than that of the first metal layer 6, specifically about 1˜100 nm, thus it can provide enough metal such that a thicker metal silicide may be formed in the source and drain regions, to thereby decrease the source-drain resistance.

Referring to FIGS. 6 and 5, a second annealing is performed such that the second metal layer 8 passes through the first metal silicide 7 to react with the Si in the source and drain regions 4 (specifically the heavily-doped source and drain regions 4B) as well as the first metal silicide 7, to thereby form a second metal silicide 9. The second annealing may be, e.g., annealing for 30s at 450˜500 □ such that the formed second metal silicide 9 includes one of NiSi, NiPtSi, NiCoSi and NiPtCoSi, or combinations thereof, and has a lower resistance. It shall be noted that in the prior art, the Ni-based metal passes through the grain boundaries of the metal-rich phase silicide such as NiSi and Ni₂Si at a faster speed, that is why the metal silicide grows laterally. While in the second annealing process of the present invention, the Si in the substrate 1 as well as the source and drain regions 4 may diffuse to pass through the first metal silicide 7 to react with the second metal layer 8, however, since the first metal silicide 7 is the epitaxially gown ultra-thin silicon-rich phase silicide, substantially no or few grain boundaries exist, the speed at which the Ni-based metal in the second metal layer 8 diffuses to the source and drain regions 4 is greatly reduced, and because the diffusion speed of Si is less than that of Ni, finally the difference in the diffusion speed will cause the second metal silicide 9 to substantially grow in a direction perpendicular to the surface of the substrate only, that is, substantially or completely suppressing the lateral extension of the second metal silicide 9. Accordingly, the end surface of the second metal silicide 9 adjacent to the channel region is parallel to, and is preferably flush with the side face of the gate spacer, and the second metal silicide 9 will not extend into the channel region. Finally, the unreacted second metal layer 8 is stripped off The second metal silicide 9 has a thickness greater than that of the first metal silicide 7, e.g., about 10˜50 nm.

Thereafter, similar to the traditional MOSFET process, a subsequent device structure is formed. For example, deposition is performed on the entire device to form an interlayer dielectric layer made of low-K material(s), (in the gate-last process, the steps of removing the dummy gate stack structure 3, and re-depositing high-K material(s), a metal nitride blocking layer, a metal work function layer and a cap layer to form a final gate stack structure may be also included), the interlayer dielectric layer is etched to form source-drain contact holes, and a metal and its nitride are deposited in the source-drain contact holes to form contact plugs.

In accordance with the method for manufacturing a semiconductor device of the present invention, by means of epitaxially growing an ultra-thin metal silicide on the source and drain regions, the grain boundaries among silicide particles are minimized or eliminated, the metal diffusion speed and direction are limited, thus the lateral growth of the metal silicide is suppressed and the device performance is further increased.

Although the present invention is described with reference to one or more illustrative embodiments, it may be appreciated by a person skilled in the art that various appropriate variations and equivalent modes may be made to the structure of the device without departing from the scope of the present invention. Furthermore, many modifications that may be applicable to specific situations or materials can be made from the teachings disclosed above without departing from the scope of the present invention. Therefore, the present invention shall be not limited to the specific embodiments disclosed as the preferred embodiments for implementing the present invention, the disclosed device structure and the manufacturing method will include all embodiments falling within the scope of the present invention.

1. A method for manufacturing a semiconductor device, comprising the steps of:
forming a gate stack structure on a substrate;
forming source and drain regions as well as a gate spacer on both sides of the gate stack structure;
depositing a first metal layer on the source and drain regions;
performing a first annealing such that the first metal layer reacts with the source and drain regions, to epitaxially grow a first metal silicide;
depositing a second metal layer on the first metal silicide; and
performing a second annealing such that the second metal layer reacts with the first metal silicide as well as the source and drain regions, to form a second metal silicide;
wherein the first metal layer has an ultra-thin thickness such that the first metal silicide can be thin enough to have no or very few grain boundaries only.

2. The method for manufacturing a semiconductor device according to claim 1, wherein the gate spacer comprises one of an oxide and a nitride, or a combination thereof.

3. The method for manufacturing a semiconductor device according to claim 1, wherein the step for forming the source and drain regions as well as the gate spacer further comprises:
performing a first source/drain ion implantation by taking the gate stack structure as a mask, to form lightly-doped source and drain extension regions in the substrate on both sides of the gate stack structure;
forming a gate spacer in the substrate on both sides of the gate stack structure;
performing a second source/drain ion implantation by taking the gate spacer as a mask, to form heavily-doped source and drain regions in the substrate on both sides of the gate spacer; and
performing annealing to activate the doped ions.

4. The method for manufacturing a semiconductor device according to claim 1, wherein the substrate comprises one of bulk Si and SOI.

5. The method for manufacturing a semiconductor device according to claim 1, wherein the first metal layer and/or the second metal layer is a Ni-based metal layer, including one of Ni, Ni—Pt, Ni—Co and Ni—Pt—Co, or any combinations thereof.

6. The method for manufacturing a semiconductor device according to claim 5, wherein the total content of non-Ni elements in the first metal layer is less than or equal to 10% in Moles.

7. The method for manufacturing a semiconductor device according to claim 1, wherein the first metal layer has a thickness of about 0.5˜5 nm.

8. The method for manufacturing a semiconductor device according to claim 1, wherein the second metal layer has a thickness of about 1˜100 nm.

9. The method for manufacturing a semiconductor device according to claim 1, wherein the first metal silicide has a thickness of about 1˜9 nm.

10. The method for manufacturing a semiconductor device according to claim 1, wherein the first metal silicide comprises one of NiSi_{2-y}, NiPtSi_{2-y}, NiCoSi_{2-y} and NiPtCoSi_{2-y}, or combinations thereof, wherein 0≦y<1.

11. The method for manufacturing a semiconductor device according to claim 1, wherein the second metal silicide comprises one of NiSi, NiPtSi, NiCoSi and NiPtCoSi, or combinations thereof.
